(19) United States
(12) Patent Application Publication
(10) Pub. No.: US 2005/0181584 A1
(43) Pub. Date: Aug. 18, 2005

(54) Ion implantation

(75) Inventors: Majeed Foad, Sunnyvale, CA (US); Bernard Harrison, West Sussex (GB); Marvin Farley, Ipswich, MA (US); Peter Kindersley, Horsham (GB); Stephen Wells, West Sussex (GB); Geoffrey Ryding, Manchester, MA (US); Takao Sakase, Rowley, MA (US)

Correspondence Address: Robert J. Mulcahy;Applied Materials, Inc., Box 450A, Santa Clara, CA, 95052, US

(73) Assignee: APPLIED MATERIALS, INC.

(21) Appl. No.: 11/029,646

(22) Filed: Jan. 6, 2005

(30) Foreign Application Priority Data
Jan. 9, 2004 (GB) 040045.9

(51) Int. Cl. H01L 21/66; G21K 5/10; H01L 21/425

(52) U.S. Cl. 438/514; 438/14; 250/492.2; 250/492.22

(57) ABSTRACT

This invention relates to a method of implanting ions in a substrate using an ion beam where instabilities in the ion beam may be present and to an ion implanter for use with such a method. This invention also relates to an ion source for generating an ion beam that can be switched off rapidly. In essence, the invention provides a method of implanting ions comprising switching off the ion beam when an instability has been detected whilst continuing motion of the substrate relative to the ion beam to leave an unimplanted portion of a scan line across the substrate, establishing a stable ion beam once more and finishing the scan line by implanting the unimplanted portion of the path.

### FIELD OF THE INVENTION

This invention relates to a method of implanting ions in a substrate using an ion beam where instabilities in the ion beam may be present and to an ion implanter for use with such a method. This invention also relates to an ion source for generating an ion beam that can be switched off rapidly.

### BACKGROUND OF THE INVENTION

Ion implanters are well known and generally conform to a common design as follows. An ion source produces a mixed beam of ions from a pre-cursor gas or the like. Only ions of a particular species are usually required for implantation into a substrate, for example a particular dopant for implantation into a semiconductor wafer. The required ions are selected from the mixed ion beam using a mass-analysing magnet in association with a mass-resolving slit. Hence, an ion beam containing almost exclusively the required ion species emerges from the mass-resolving slit to be transported to the process chamber where the ion beam is incident on a substrate held in place in the ion beam path by a substrate holder.

Frequently, an ion beam used for implantation has a smaller cross-sectional area than the substrate to be implanted. In order to ensure ion implantation across the whole of the substrate, the ion beam and substrate are moved relative to one another such that the ion beam scans the entire substrate surface. This may be achieved by (a) deflecting the ion beam to scan across the substrate which is held in a fixed position, (b) mechanically moving the substrate whilst keeping the ion beam path fixed, or (c) deflecting the ion beam and moving the substrate.

Substrates are generally implanted serially one after another or as a batch at one time: for serial processing, relative motion between ion beam and substrate is effected such that the ion beam traces a raster pattern on the substrate surface by scanning to and fro across the substrate to form a series of parallel, equally-spaced scan lines; for batch processing, the substrates are held on spokes of a rotating wheel such that the ion beam scans across each substrate in a series of scan lines that form adjacent arcs.

To achieve uniform implantation, there must be adequate overlap between adjacent scan lines. Put another way, if the spacing between adjacent scan lines (with respect to the ion beam width profile) is too great, “striping” of the substrate will result with periodic bands of increased and decreased doping levels.

The precautions described above cannot be effected if the ion beam incident on the substrate is not itself uniform over time. Unfortunately, instabilities of the ion beam are inevitable and result from discharges in the ion source area for example. The effect of these instabilities is that there is a “glitch” in the ion beam in that the flux will usually drop significantly within a short period of time. The drop in ion beam flux leads to areas of the semiconductor wafer receiving a lower level of doping that may lead to the production of faulty semiconductor devices. More unusually, a rapid rise is seen in the ion beam flux. Again, this produces incorrect dosing that may lead to faulty devices.

The above problem is particularly severe for serial processing ion implanters that use mechanically scanned substrate holders, as will now be explained. To create the raster pattern, the substrate holder is moved in a reciprocating fashion and there is a limit to the maximum speed at which this can be done. To date this has been far lower than the scanning speeds that can be achieved with rotating batch substrate holders. Fast scan speeds require the ion beam to make many passes over the substrate to achieve a desired dosing: any instability in the beam during a single pass leads to a small residual dosing error due to dilution by the many subsequent passes. The adverse effects are far more severe in serial processing where the slow scan speeds result in fewer passes to achieve the same dosing.

The problem of ion beam instabilities has been addressed previously, see The Ion Beam Optics of a Single Wafer High Current Ion Implanter by White et al., Proceedings of the Eleventh International Conference on Ion Implantation Technology, North Holland (1997), pages 396-399. However, this disclosure is made in the context of high-current implantation using a ribbon beam (i.e. a beam with a width wider than the substrate such that scanning in effected in the direction perpendicular to the beam's width only rather than with two-dimensional, mechanical scanning). Upon detecting a beam instability during a scan, the ion beam is gated off for the rest of the scan. The scan is then repeated in the reverse direction and the ion beam gated off once more upon reaching the position corresponding to where the instability had been detected.

Hence, there is a demand for methods of addressing the problem of ion beam instability such that a uniform dosing of a substrate can be achieved, particularly for systems using an ion beam of a smaller size than the substrate and also for mechanically-scanned implantation.

### SUMMARY OF THE INVENTION

According to a first aspect, the present invention resides in a method of implanting ions in a substrate using an ion beam having cross-sectional dimensions smaller than the substrate comprising the steps of: (a) establishing a stable ion beam with the substrate clear of the ion beam; (b) implanting the substrate by causing relative motion between the ion beam and the substrate such that the ion beam traverses the substrate along at least one path; (c) monitoring the ion beam for instabilities during step (b); (d) upon detecting an ion beam instability, switching off the ion beam as the relative motion continues to leave an unimplanted portion of the path; (e) recording an off position corresponding to the ion beam's position relative to the substrate when the ion beam is switched off in step (d); (f) establishing a stable ion beam once more; and (g) continuing to implant the substrate by causing relative motion between the ion beam and the substrate along the unimplanted portion of the path.

Extinguishing the ion beam upon detecting an instability is advantageous as it stops implantation and thus avoids creating an area of non-uniform implantation in the substrate.

Recording the off position is beneficial as it allows control of further implantation to ensure uniform dosing of the substrate. The off position may be recorded when an action is taken to switch off the ion beam (e.g. interrupting power to an ion source). If this is done, it is clearly advantageous for the ion beam to be switched off rapidly. Where there is a known latency in switching off the ion beam, the off position may be recorded as the position where the action is taken to switch off the ion beam plus the distance corresponding to this latency.

Alternatively, the ion beam flux may be monitored and the off position may be recorded when the ion beam flux is zero or drops below a threshold. Clearly, the phrase “recording an off position corresponding to the ion beam's position relative to the substrate when the ion beam is switched off” can be construed to cover these possibilities.

In addition, a profile of the ion beam may be taken to identify any changes in beam shape of movements in the centre of the beam. Any changes identified may be corrected by tuning the beam or by slightly altering the position of the beam as it follows the path.

The relative motion may form a series of scan lines that extend in parallel and the scan lines may, optionally, form a raster pattern.

The relative motion between ion beam and substrate is preferably controlled to ensure the same dosing as for the previously implanted portion of the path. For example, the same relative speed should be used if the ion beam has the same flux as before it was extinguished. If a difference in ion beam flux is determined, the relative speed may be adjusted to ensure the same dosing (i.e. the relative speed may be measured in response to an increase in ion beam flux).

According to one embodiment, step (f) comprises establishing a stable ion beam with the substrate clear of the ion beam prior to step (g); step (g) comprises causing relative motion between the ion beam and the substrate such that the ion beam travels along said path in a reverse direction, that is in an opposite direction as for step (b); and switching off the ion beam when the ion beam crosses the off position.

Restarting the ion beam clear of the substrate avoids non-uniformities in implanting as the ion beam settles to a stable flux. In addition, extinguishing the ion beam can be performed rapidly and so the drop in dosing concentration is abrupt. Moreover, the exact timing of switching the ion beam off as it reaches the off position can be adjusted to optimise overlap of any short tailing-off regions where the ion beam is extinguished. As the ion beam is scanned in the reverse direction, the overlap of the tailing-off regions complement each other to give the desired uniformity.

According to a second embodiment, step (g) further comprises switching the ion beam on at the off position prior to the ion beam traversing the unimplanted portion of said path in the forward direction, that is the same direction as for step (b). Preferably, step (g) comprises causing relative motion between the ion beam and substrate in the forward direction from a point along said path such that the ion beam is switched on upon crossing the off position. After starting the ion beam, there is a brief period where the ion beam flux increases to its stable value. This behaviour can be determined and the operation of the ion implanter adjusted to ensure the tailing-off region where the ion beam was extinguished complements the ramping-up region where the ion beam is restarted to give uniform dosing. The exact timing of when the relative speeds of ion beam and substrate can be adjusted to provide uniform dosing.

Where recovery is performed by scanning in the reverse direction, the method may further comprise repeating steps (c), (d) and (e) during step (g) such that, if a second beam instability is detected, a central portion of said path is not implanted; and continuing to implant the substrate once more by causing relative motion between the ion beam and the substrate such that the ion beam travels across the substrate along the central portion of said path. Preferably, the method comprises the steps of commencing the relative motion along said path outside of the central portion, switching the beam on when first crossing an off position and switching the beam off when crossing the other off position. As will be appreciated, this dosing may be performed in either direction.

From a second aspect, the present invention resides in a method of implanting ions in a substrate held in a substrate holder moveable bidirectionally along a first axis of translation, the method comprising the steps of: (a) establishing a stable ion beam having cross-sectional dimensions smaller than the substrate with the ion beam clear of the substrate in a start position adjacent the substrate along the first axis; (b) implanting the substrate by moving the substrate holder along the first axis such that the ion beam transverses the substrate along a first scan line and continues until clear of the substrate; (c) causing relative motion between the ion beam and the substrate holder along a second axis; (d) repeating steps (b) and (c) to implant a series of scan lines across the substrate; (e) monitoring the ion beam during implantation in step (b) and as repeated according to step (d); (f) upon detecting an ion beam instability, switching off the ion beam as the relative motion continues to leave an unimplanted portion of the scan line; (g) recording an off position corresponding to the position of the substrate holder when the ion beam is switched off in step (f); (h) establishing a stable ion beam once more; (i) completing implantation of the scan line by moving the substrate holder along the first axis so that the ion beam scans over the unimplanted portion of the scan line; and (j) completing implantation of the substrate by repeating steps (b) and (c) to complete the series of scan lines across the substrate.

Movement along the first axis may form a series of scan lines that extend in parallel and the scan lines may, optionally, form a raster pattern. The movement may be in one direction along the first axis or may be in both directions along the first axis.

Preferably step (c) comprises translating the substrate holder along a second axis of translation relative to a fixed ion beam, the first and second axes being perpendicular. Alternatively, the ion beam may be deflected along such a second axis.

From a third aspect, the present invention resides in an ion implanter controller for an ion implanter operable to generate an ion beam for implanting into a substrate, the controller comprising: ion beam switching means operable to cause the ion beam to switch on and off; scanning means operable to cause relative motion between the ion beam and the substrate such that the ion beam traverses the substrate along at least one path; ion beam monitoring means operable to receive a signal indicative of the ion beam flux and to detect instabilities in the ion beam therefrom during said relative motion; and indexing means operable to determine the position of the ion beam relative to the substrate during said relative motion; wherein the controller is arranged such that: the ion beam switching means is operable to cause the ion beam to switch off during the relative motion when the ion beam monitoring means detects an instability in the ion beam to leave an unimplanted portion of the path; the indexing means records an off position of the ion beam relative to the substrate when the ion beam is switched off; the ion beam switching means is operable to cause the ion beam to switch on once more; and the scanning means is operable to cause relative motion between the ion beam and the substrate such that the ion beam traverses the substrate along the unimplanted part of the path.

The ion implanter controller may be embodied in hardware or software form, i.e. parts of the controller may be implemented electronically or using software provided on a computer or the like. In fact, a part-hardware and part-software implementation could be followed where some parts are based on electronic components and others are based in software.

Movement along the first axis may form a series of scan lines that extend in parallel and the scan lines may, optionally, form a raster pattern. The movement may be in one direction along the first axis or may be in both directions along the first axis.

From a fourth aspect, the present invention resides in an ion implanter for implanting a substrate using an ion beam, including the controller described herein above.

From a fifth aspect, the present invention resides in an ion source for an ion implanter comprising: a cathode; an anode; biasing means for biasing the anode relative to the cathode; a first switch; and a first electrical path connecting anode to cathode via the biasing means and switch arranged in series; wherein the first switch is operable to make or break the first electrical path. This simple arrangement rapidly isolates the biasing means that otherwise biases the anode relative to the cathode. Hence, an ion beam may be rapidly extinguished when an instability is detected.

Optionally, the ion source further comprises a second conductor path connecting anode to cathode with at least a portion that extends in parallel across the biasing means, the portion comprising a second switch operable to make or break the second electrical path. Preferably, the first switch is operable in response to a first binary switching signal and the second switch is operable in response to a second binary switching signal that is the complement of the first switching signal. This allows a convenient way of switching the potential of the anode to be biased either relative to the cathode or at the same potential as the cathode. When a potential difference exists, an ion beam is produced: when no potential difference exists, there is no ion beam.

Preferably, the first switch and/or any second switch is a power semiconductor switch as this allows particularly rapid switching and hence particularly rapid extinction or creation of an ion beam.

The present invention also extends to an ion implanter including the ion source described herein above and to a method of switching such an ion source comprising the step of operating the first switch to break the first electrical path in response to detection of an instability in the ion beam generated by the ion source.

This method may be accompanied by the steps of maintaining or increasing the power supplied to the cathode. For example, the ion source may comprise an indirectly heated cathode and three power supplies: a filament supply (for the cathode's filament), a bias supply (for biasing within the indirectly heated cathode) and an arc supply (for biasing the anode relative to the cathode). Power supplied by the filament supply and the bias supply may be maintained, or may be increased to match the power of the arc supply prior to operating the first switch. This is to minimise any cooling in the ion source, and in the cathode in particular, when arc discharging ceases. Indirectly heated cathodes comprise a filament in front of an end cap. Increasing power supplied by the filament supply generates more electrons to be accelerated into the end cap, whilst increasing the power supplied by the bias supply increases the energy with which the electrons strike the end cap: in either case, the cathode enjoys greater heating from the electrons to compensate for the heating otherwise provided by the arcing.

Other preferred features of the invention are set forth in the appended claims.

### BRIEF DESCRIPTION OF THE DRAWINGS

Examples of the invention will now be described with reference to the accompanying drawings, in which:

FIG. 1 is a schematic view of an ion implanter having a wafer holder for serial processing of wafers;

FIG. 2 is a simplified representation of an ion source for use in an ion implanter showing the power supply units used for biasing various parts of the ion source;

FIG. 3 shows a raster scan of an ion beam across a wafer adopted in serial processing;

FIGS. 4a to 4d show an ion beam scanning scheme according to a first embodiment of the present invention for use during ion implantation where a glitch in the ion beam is detected;

FIGS. 5a to 5d correspond to FIGS. 4a to 4d but for a second embodiment of the present invention;

FIGS. 6a to 6d correspond to FIGS. 4a to 4d but shows a case where two glitches in the ion beam occur in the same scan line;

FIG. 7 is a schematic view of an ion implanter including a first embodiment of a return current monitor;

FIG. 8 is a schematic view of an ion implanter including a second embodiment of a return current monitor; and

FIG. 9 corresponds to FIG. 2 but shows a modification of the arc power supply unit arrangement.

### DESCRIPTION OF THE PREFERRED EMBODIMENTS

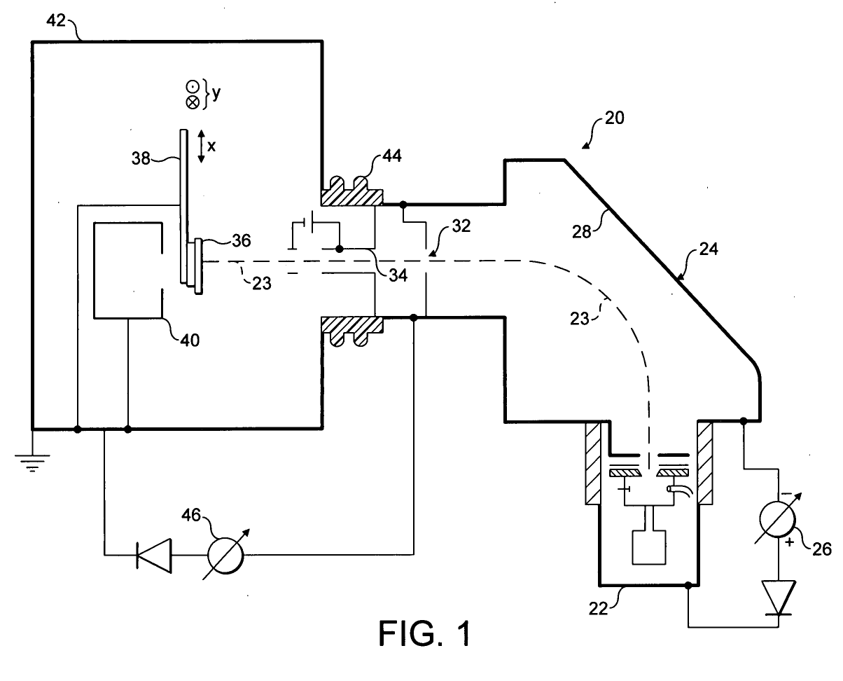

FIG. 1 shows a typical ion implanter 20 comprising an ion beam source 22 such as a Freeman or Bernas ion source that is supplied with a pre-cursor gas for producing an ion beam 23 to be implanted into a wafer. The ions generated in the ion source 22 are extracted by an extraction electrode assembly. The flight tube 24 is electrically isolated from the ion source 22 and a high-tension power supply 26 supplies a potential difference therebetween.

This potential difference causes positively charged ions to be extracted from the ion source 22 into the flight tube 24. The flight tube 24 includes a mass-analysis arrangement comprising a mass-analysing magnet 28 and a mass-resolving slit 32. Upon entering the mass-analysis apparatus within the flight tube 24, the electrically charged ions are deflected by the magnetic field of the mass-analysis magnet 28. The radius and curvature of each ion's flight path is defined, through a constant magnetic field, by the mass/charge ratio of the individual ions.

The mass-resolving slit 32 ensures that only ions having a chosen mass/charge ratio emerge from the mass analysis arrangement. In fact, the ion source 22 and mass analysing magnet 28 are rotated through 90° when compared to the arrangement of FIG. 1, so that the ion beam 23 would initially travel perpendicular to the plane of the paper. The ion beam 23 is then turned by the mass-analysing magnet 28 to travel along the plane of the paper. Ions passing through the mass-resolving slit 32 enter a tube 34 that is electrically connected to and integral with the flight tube 24. The mass-selected ions exit the tube 34 as an ion beam 23 and strike a semiconductor wafer 36 mounted upon a wafer holder 38. A beamstop 40 is located behind (i.e. downstream of) the wafer holder 38 to intercept the ion beam 23 when not incident upon the wafer 36 or wafer holder 38. The wafer holder 38 is a serial processing wafer holder 38 and so only holds a single wafer 36. The wafer holder 38 is operable to move along X and Y axes, the direction of the ion beam 23 defining the Z axis of a Cartesian coordinate system. As can be seen from FIG. 1, the X axis extends parallel to the plane of the paper, whereas the Y axis extends into and out from the plane of the paper.

To maintain the ion beam current at an acceptable level, an ion extraction energy is set by a regulated high-tension power supply 26: the flight tube 24 is at a negative potential relative to the ion source 22 by virtue of this power supply 26. The ions are maintained at this energy throughout the flight tube 24 until they emerge from the tube 34. It is often desirable for the energy with which the ions impact the wafer 36 to be considerably lower than the extraction energy. In this case, a reverse bias voltage must be applied between the wafer 36 and the flight tube 24. The wafer holder 38 and beamstop 40 are contained within a process chamber 42 that is mounted relative to the flight tube 24 by insulating standoffs 44. Both the beamstop 40 and wafer holder 38 are connected to the flight tube 24 via a deceleration power supply 46. The beamstop 40 and wafer holder 38 are held at a common ground potential so that, to decelerate the positively-charged ions, the deceleration power supply 46 generates a negative potential with respect to the grounded wafer holder 38 and beamstop 40 at the flight tube 24.

In some situations, it is desirable to accelerate the ions prior to implantation in the wafer 36. This is most easily achieved by reversing the polarity of the power supply 46. In other situations, the ions are left to drift from flight tube 24 to wafer 36, i.e. without acceleration or deceleration. This can be achieved by providing a switched current path to a short out the power supply 46.

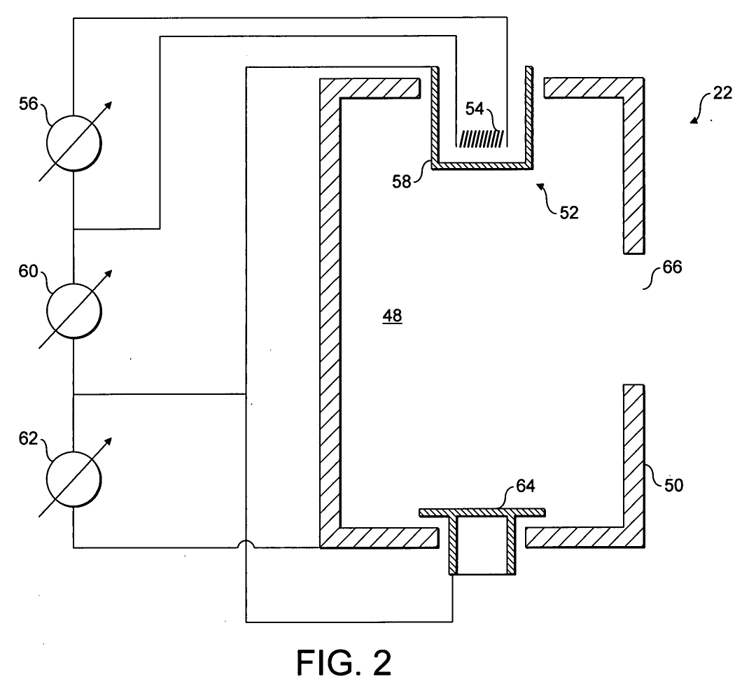

Turning now to FIG.2, a typical ion source 22 is shown along with its associated power supply units. The ion source 22 comprises an ion source chamber 48 enclosed by chamber walls 50. The ions are produced in a plasma by emitting electrons from a cathode 52 located within the ion source chamber 48 and by biasing the chamber walls 50 to form an anode. In this ion source 22, an indirectly heated cathode 52 is used.

The indirectly heated cathode 52 comprises a filament 54 supplied by a filament power supply unit 56. The filament supply 56 provides sufficient current to cause thermionic emission of electrons from the filament 54. The indirectly heated cathode 52 also comprises a tube 58 enclosing the filament 54 that is connected across a bias power supply unit 60 such that the tube 58 is at a positive potential relative to the filament 54. This ensures that electrons emitted by the filament 54 are attracted and accelerated into the end-cap of the tube 58. The impacts of the electrons heat the end-cap of the tube 58 such that it emits electrons into the ion source chamber 48.

The chamber walls 50 are held at a positive potential relative to the tube 58 by virtue of their connection to an arc power supply unit 62. Accordingly, electrons emitted by the tube 58 are attracted to the chamber walls 50. In fact, the motion of the electrons emitted from the cathode 52 is constrained by creating a magnetic field across the ion source 22 using a pair of coils of an associated electromagnet (not shown). The magnetic field created is such that electrons emitted by the cathode 52 follow a spiral path towards the far end of the ion source chamber 48.

Located at this far end is a counter-cathode 64 also connected to the bias supply 60 so as to be at the same potential as the tube 58 of the indirectly heated cathode 52. Accordingly, electrons approaching the counter-cathode 64 are repelled such that they travel back along the spiral path in a reverse direction. This increases the chances of electrons interacting with the pre-cursor gas that fills the ion source chamber 48 thereby creating more ions that may be extracted through an aperture 66 provided in the chamber walls 50 to form the ion beam 23.

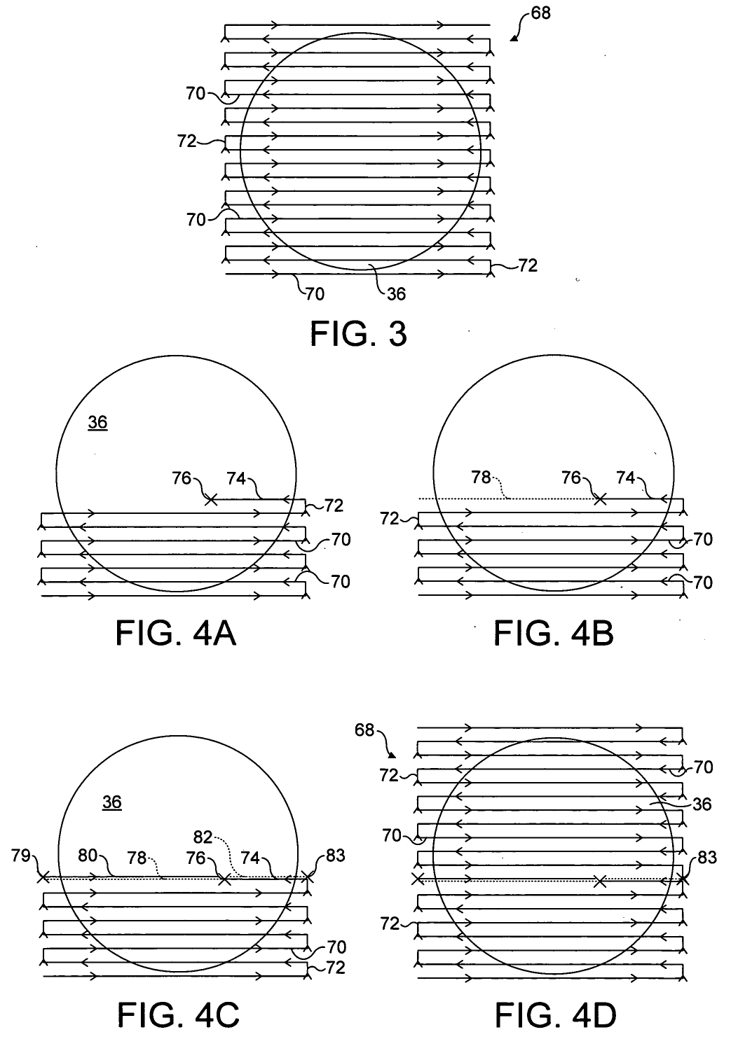

As described previously, the wafer holder 38 can be moved along the X and Y axes. Movement of the wafer holder 38 is controlled such that the fixed ion beam 23 scans across the wafer 36 according to the raster pattern 68 shown in FIG. 3. Although the wafer 36 is scanned relative to a fixed ion beam 23, the raster pattern 68 of FIG. 3 is equivalent to the ion beam 23 being scanned over a stationary wafer 36 (and this method is in fact used in some ion implanters). As imagining a scanning ion beam 23 is more intuitive, the following description will follow this convention although in fact the ion beam 23 is stationary and it is the wafer that is scanned.

The ion beam 23 is scanned over the wafer to form a raster pattern of parallel, spaced scan lines 70. This is achieved by scanning the ion beam 23 forwards along the X-axis direction to form the first scan line 70 until the ion beam is clear of the wafer 36, moving the ion beam 23 up along the Y-axis direction as shown at 72, scanning the ion beam 23 backwards along the X-axis direction until clear of the wafer 36 once more, moving the ion beam 23 up along the Y-axis direction 72, and so on until the whole wafer 36 has seen the ion beam 23.

During scanning of the ion beam 23 across the wafer 36, the ion beam current is measured such that any glitches in ion beam flux can be detected. A detailed description of how the ion beam current is measured and the conditions that correspond to a glitch follows later. As scanning is performed by moving the wafer holder 38 in a controlled manner, the position of the ion beam 23 relative to the wafer 36 is known at any instant. Hence, the position of the ion beam 23 on the wafer 36 at the instant a glitch is detected or at the instant the ion beam 23 is turned off may be determined.

FIG. 4a shows the initial stages of a raster scan 68 formed during implantation. Seven complete scan lines 70 have been formed on the wafer 36. However, a glitch in the ion beam 23 is detected during the eighth scan line 74. The ion implanter 20 responds to detection of the glitch by extinguishing the ion beam 23 as rapidly as possible. Extinguishing the ion beam 23 results in the ion beam 23 switching off at the position shown in FIG. 4a at 76 and this position is duly recorded as an “off” position with reference to the known position of the wafer holder 38.

Movement of the wafer holder 38 continues along the scan line when and after the ion beam 23 is extinguished such that the ion beam 23, were it still switched on, would follow the remainder of the current scan line in a forward direction to end beyond the far side of the wafer 36 at the position 79 (this movement is shown by the dashed line 78 in FIG. 4b). In FIGS. 4 to 6, a solid line denotes movement of the wafer holder 38 with the ion beam 23 switched on whereas a dashed line denotes movement of the wafer holder 38 with the ion beam 23 switched off.

In this position 79, the ion beam 23 is switched on once more and is monitored to detect when stability has been achieved. Upon confirmation of a stable ion beam 23, the wafer holder 38 is moved once more such that it follows the current scan line, but in the reverse direction as shown by the solid line 80. FIG. 4c shows lines 78 and 80 offset from each other for the sake of clarity: in fact, the path of the ion beam 23 (whether switched on or off) is usually coincident upon the same scan line 74. Accordingly, the remainder of the current scan line 74 is implanted. To ensure uniform implantation across the entire scan line 74, the same rapid extinction of the ion beam 23 is performed at the “off” position 76 where the ion beam 23 was extinguished following detection of the glitch. This is shown in FIG. 4c, where upon reaching the “off” position 76, the wafer holder 38 continues to move along the scan line 70 in a reverse direction, such that, if the ion beam 23 were still switched on, it would scan across the wafer 36 to finish at position 83 adjacent to the edge of the wafer 36 (the movement is shown by the dashed line 82).

The ion beam 23 is restarted once more at 83 and, upon confirmation of a stable ion beam 23, the remainder of the raster scan 68 is performed as shown in FIG. 4d. In this way, uniform implantation across the entire wafer 36 is achieved.

It is inadvisable to restart the ion beam 23 when it will be incident upon the wafer 36 as this will dose further the wafer 36 at that point. In addition, it is inadvisable to restart the ion beam 23 when it will be incident upon the wafer holder 38 as this may produce contamination. This may be the case as the wafer holder 38 extends adjacent the wafer 36 along the X-axis and so a movement along the X-axis direction alone may not be enough to ensure the ion beam is clear of the wafer holder 58. Accordingly, after a scan line 70 has been followed with the ion beam 23 switched off following a glitch, the wafer holder 38 is moved in the Y-axis direction prior to restarting the ion beam 23 if it would otherwise strike the wafer holder 38. Once a stable ion beam 23 is obtained, the wafer holder 38 is moved back along the Y-axis direction and the next movement along a scan line 70 is performed.

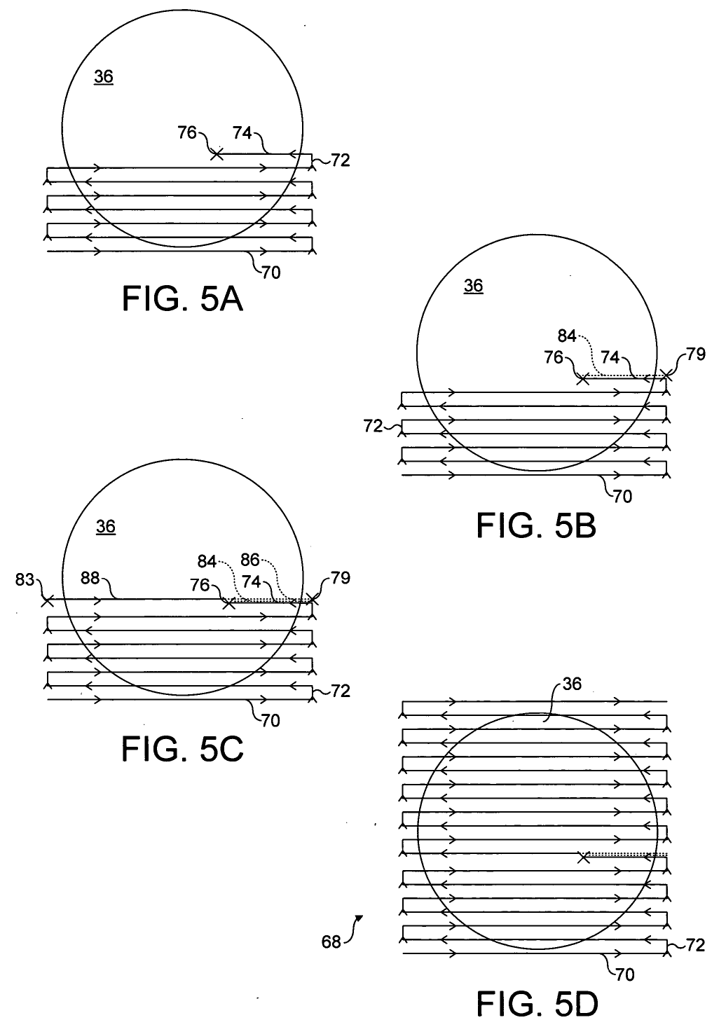

An alternative method for recovering from a glitch in the ion beam 23 is shown in FIGS. 5a to 5d. The same starting conditions as described for FIG. 4a are assumed and these are reflected in FIG. 5a where the ion beam 23 is extinguished during forward motion along a scan line 74 at the “off” position 76 shown.

In addition to extinguishing the ion beam 23, movement of the wafer holder 38 is stopped and then reversed such that, if the ion beam 23 were still switched on, it would follow the current scan line 74 but in the reverse direction to end up clear of the wafer 36 at 79. This movement is reflected in FIG. 5b by the dashed line 84.

Movement of the wafer holder 38 is started once more, with the ion beam 23 still switched off, such that the ion beam 23 would follow the current scan line 74 in the forwards direction as shown by the dashed line 86. When the “off” position 76 is reached, the ion beam 23 is switched on rapidly while movement of the wafer holder 38 continues to complete the current scan line 70. This is shown in FIG. 5c by the solid line 88 that ends at 83 and results in a uniform implantation of that scan line 74. As shown in FIG. 5d, scanning can continue to complete the raster scan 68 and therefore achieve uniform implantation of the entire wafer 36.

The method of FIGS. 4a to 4d is preferred to the method of FIGS. 5a to 5d. This is because the ion beam 23 can be extinguished faster than it can be turned on, and turning the ion beam 23 on inevitably produces uneven dosing while the ion beam 23 settles.

Of course, the possibility exists that a further beam instability may occur during a second pass 80;88 along a scan line 74 where a previous glitch is being repaired. Were this to happen in the method described with relation to FIGS. 5a to 5d, this can easily be overcome by repeating the same method time and time again. Specifically, the wafer holder 38 can be translated 84 back to the start position 79 of the current scan line 70, the wafer holder 38 moved 84 along the current scan line 70 and the ion beam 23 is switched on rapidly when it reaches the previous “off” position 76. In this way, the entire scan line 70 is implanted over a number of successive passes in the same direction.

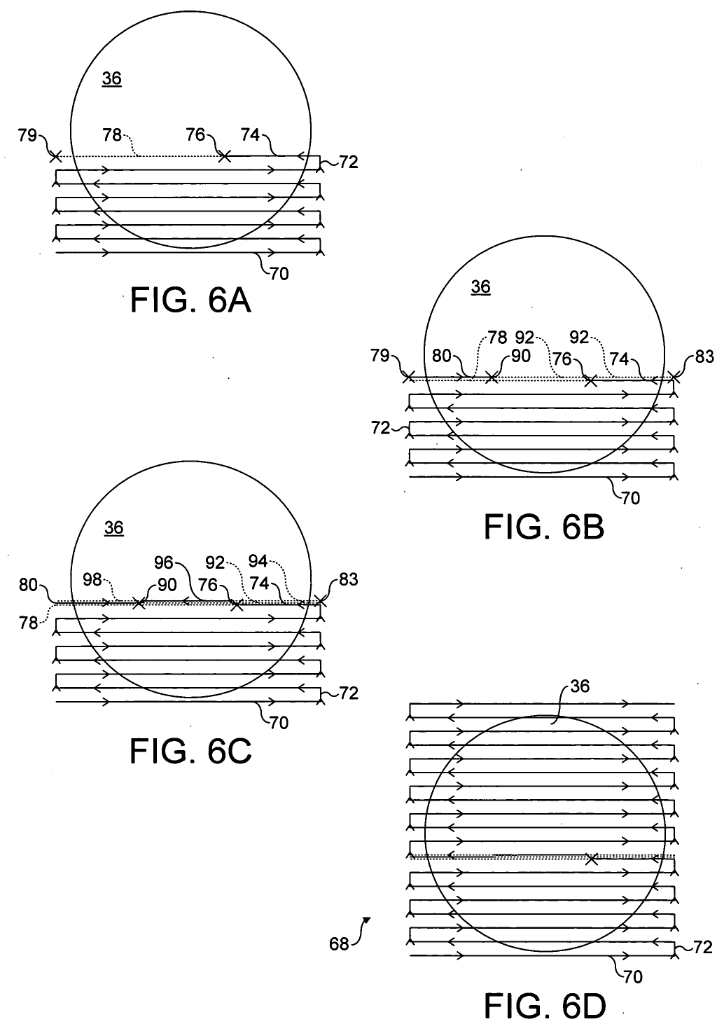

Clearly the situation is different for the method already described with respect to FIGS. 4a to 4d. A hybrid method of recovering from two glitches is adopted which will now be described with reference to FIGS. 6a to 6d. FIG. 6a corresponds to FIG. 4b and so describes the situation where an ion beam 23 glitch has been detected, the ion beam 23 has been switched off at 76 and the wafer holder 38 has been moved such that the ion beam 23, if it were switched on, travels along line 78 to finish at 79 to the side of the wafer.

FIG. 6b shows the start of the recovery operation where the ion beam 23 is switched on at 79 and, upon confirmation of a stable ion beam 23, the wafer holder 38 is moved such that implantation occurs along the current scan line 74 in the reverse direction as shown by 80. However, at the point 90 indicated in FIG. 6b a further glitch is detected and the ion beam 23 is switched off and the second “off” position 90 recorded.

The ion beam 23 is extinguished while translation of the wafer holder 38 continues such that, if the ion beam 23 were still switched on, it would follow the current scan line 70 along the reverse direction to reach the far side of the wafer 36 at 83 (the movement is shown by the dashed line 92). Movement of the wafer holder 38 is then reversed to follow the current scan line 70 in a forwards direction and continues along the entire length of the current scan line 70. During this movement, initially the ion beam 23 is switched off as shown by 94, the ion beam 23 is switched on when reaching the first “off” position 76 to form the line 96 and is then switched off upon reaching the second “off” position 90 to continue as dashed line 98.

Accordingly, the remaining central portion of the current scan line 70 is implanted thereby forming a complete scan line 70 with uniform implantation. As before, the remainder of the wafer 36 can be implanted using the standard raster pattern 68 as shown in FIG. 6d. As recovery from the second ion glitch relies upon the inferior method of restarting the ion beam 23 while scanning across the wafer 36, it is important to check the stability of the ion beam 23 when first restarting the ion beam 23 at position 79. Obviously, it is best to avoid the need to recover from two glitches in a single scan line 74.

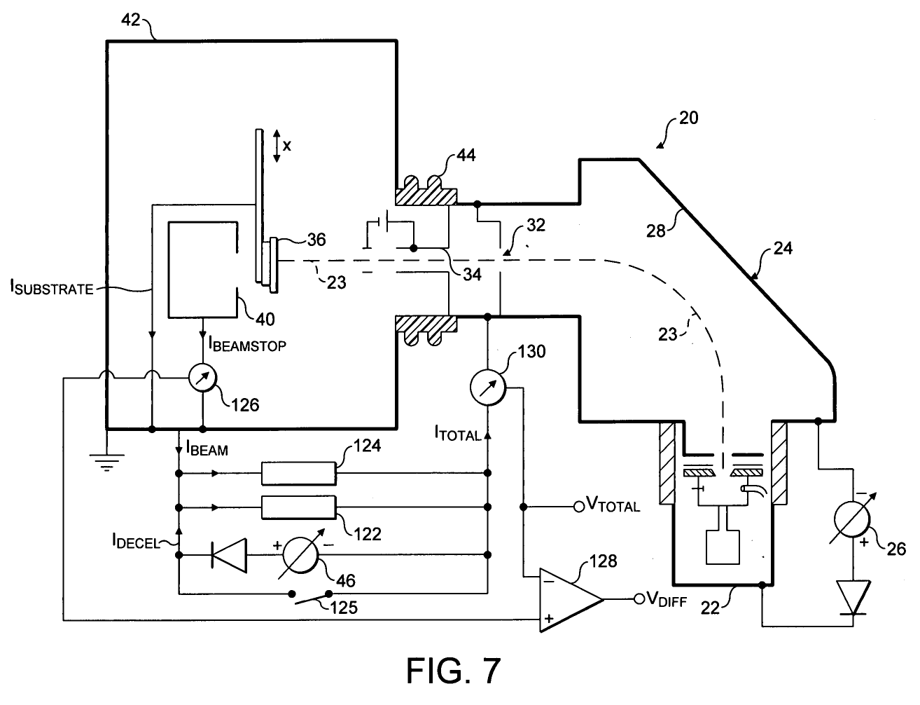

In order to determine when beam glitches occur, the ion beam current is monitored continuously by using a return current monitor. This arrangement will now be described with reference to FIG. 7.

As mentioned previously, in usual operation the deceleration supply 46 generates a negative potential with respect to the grounded wafer holder 38 and beamstop 40 to decelerate positively-charged ions exiting the tube 34. In order for the deceleration power supply 46 to maintain a regulated voltage between the wafer holder 38/beamstop 40 and the flight tube 24, it is important to ensure that a forward current flows through the deceleration power supply 46 to compensate for the positively charged ions flowing between flight tube 24 and the wafer holder 38/beamstop 40. This is achieved by connecting a deceleration supply load resistance 122 in parallel with the power supply 46.

In order to provide cooling to assemblies in the beam line and ion source areas of the ion implanter 20, a closed circuit cooling water flow is required from a heat exchanger located at ground potential. The flow and return pipes must cross the post mass acceleration or deceleration voltage gaps. The water is slightly electrically conductive and part of the return current flow from the wafer 36 passes through these pipes. This represents a further effective load resistance in parallel with the deceleration power supply 46. Although the current through the water used to cool the wafer holder 38 (that is usually deionised) is typically negligible, the current return through the cooling pipes will not necessarily be negligible. For example, when high post-mass acceleration or deceleration voltages are employed, a cooling water current of several mA may arise. To take this into account, FIG. 7 shows a cooling system resistance 124 placed in parallel with the deceleration supply load resistance 122 and a deceleration power supply 46. FIG. 7 also shows a switch 125 that allows the deceleration power supply 46 to be shorted out when operating in ‘drift’ mode (described previously).

The current flowing through the deceleration supply load resistance 122 will then be the sum of the forward current through deceleration power supply I_{DECEL} and the net current I_{BEAM} absorbed by both the wafer 36 and beamstop 40 minus a small cooling system water current.

The output of the beamstop 40 is monitored by a first current monitor 126 that generates a voltage signal representative of the beamstop current. This voltage signal is connected to one input of a comparator 128, as will be described below. The ion implanter 20 also contains a second current monitor 130 arranged in the path of the total current (the sum of the beam and deceleration currents) as it returns to the flight tube 24. The second monitor 130 also generates a voltage signal V_{TOTAL} that indicates the total returning to the flight tube 24. In one embodiment, the signal V_{TOTAL} may be measured directly without comparing it to the beamstop current.

Alternatively, the signal V_{TOTAL} is fed to a second input of the comparator 128. Thus the comparator 128 generates an output V_{DIFF} representative of the difference of the beamstop current I_{BEAMSTOP} and the total current I_{TOTAL} returned to the flight tube 24.

This arrangement is described in more detail in our U.S. Pat. No. 6,608,316 that is incorporated herein in its entirety by reference. Briefly, the voltage output of the current monitor 126 is connected to a differential amplifier that fulfils the function of the comparator 128. The total current from the wafer holder 38 and beamstop 40 passes through the deceleration power supply 46, deceleration supply load resistance 122 and any cooling systems 124. The total current I_{TOTAL} is fed to a second current monitor 130 that operates in a similar manner to the first current monitor 126.

The advantages of monitoring the total current returning to the flight tube 24, instead of or as well as the beamstop 40 is that it is broadly indicative of the ion beam current at the point when it impacts the wafer holder 38/beamstop 40 assembly. Any arcing, for example, in the ion source 22 will manifest itself as a glitch in the ion beam 23. This in turn may be monitored by monitoring I_{TOTAL}. At any time during the implantation cycle, a qualitative indication of the ion beam integrity may then be obtained as is required for the method of the present invention. In particular, the voltage signal which is an output of the current monitor 130 allows wide band stability monitoring of the ion beam 23.

The arrangement shown in FIG. 7 is particularly applicable for use with batch processing of wafers 36 because problems in ripples in the current measured by the beamstop 40 are largely avoided. I_{TOTAL} is slightly distorted due to backstreaming electrons generated when the ion beam 23 is striking the wafers 36. For positively charged ions, some electrons liberated from the wafers 36 are accelerated away during ion deceleration, thus adding to the current return to the flight tube 24. The beamstop 40 effectively traps the secondary electrons but, however, there are no backstreaming electrons to augment the current when the wafer holder 38 does not occlude the ion beam 23. When the ion beam 23 is entirely incident on the beamstop 40, the beamstop current substantially equals the current beam return to the flight tube 24, i.e. I_{BEAMSTOP}≅I_{TOTAL}. Thus, the differential output of the comparator 128 is approximately zero in this instance and so can be used to distinguish the measured beam current as determined by the current beamstop measurement as opposed to the current incident upon the wafers 36.

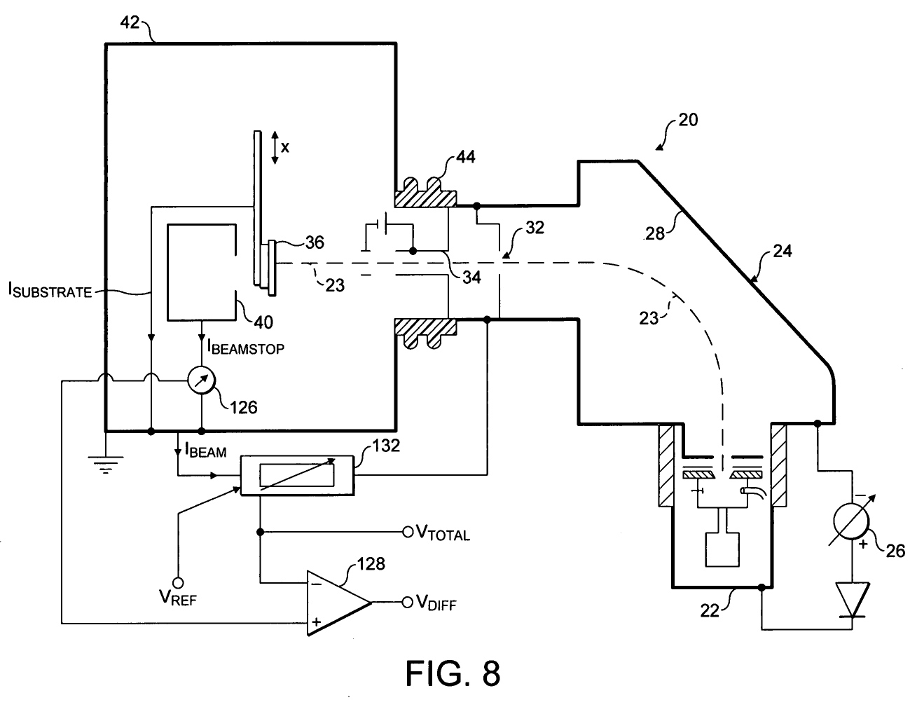

An alternative embodiment of an incident ion beam 23 current measurement arrangement is shown in FIG. 8. Many parts correspond to those shown in FIG. 7 and so are labelled with corresponding reference numerals.

As shown in FIG. 8, rather than employing a deceleration ion power supply 46, a variable resistance 132 is placed in the current path which returns the ion beam current from the wafer holder 38 and beamstop 40 back to the flight tube 24. Although the variable resistance 132 may consist of passive devices, it is preferable to use a series of active devices such as field effect transistors (FET's). The manner of operation of the device of FIG. 8 is described in more detail in the above mentioned U.S. Pat. No. 6,608,316 and in British Patent Application No. 9523982.8.

Briefly, the potential difference between the wafer holder 38/beamstop 40 (normally held at ground potential) and the flight tube 24 is controlled by varying the resistance of a chain of FET's connected in series between the wafer holder 38/beamstop 40 (at ground potential) and the flight tube 24. This is done by measuring the voltage across the FET chain, with a potential divider buffering the voltage and comparing the voltage to a reference voltage (V_{REF}) using a differential amplifier. The error signal (i.e. the amplified difference between the desired acceleration potential and the active deceleration potential) as measured by the potential divider is used to adjust the effective resistance of the FET chain.

The potential drop across the FET chain, V_{TOTAL}, is indicative of the total current return to the flight tube 24. In one embodiment, this is fed through the comparator 128 which may be a differential amplifier. The other input to the comparator 128 is a voltage representative of the beamstop current. This is derived from the beamstop current monitor 126. The output of the comparator 128 is similar to that already described with reference to FIG. 7. With the apparatus shown in FIG. 7, the voltage signal V_{TOTAL} may be measured directly rather than being compared with the beamstop current signal.

The continuous measurement of the ion beam 23 current is used to determine whether or not a beam glitch has occurred. The continuous beam current is monitored for fast changes to indicate a beam glitch, rather than looking for slow changes. This is because slow changes in the ion beam current frequently occur and may be due to such mechanisms as residual gas neutralisation of the ion beam 23. A threshold value for the rate of change can be set and this is likely to be dictated by any particular ion implantation recipe.

Any event which does not meet the slow changing criteria is assumed to indicate instability of the change is above a certain size.

Quantifying changes in the ion beam current is performed using a comparison to an average ion beam current value. This average is obtained by taking a number of readings of the ion beam current once a stable ion beam 23 has been obtained, e.g. by using a rolling average of the total current obtained by measuring the total current I_{TOTAL} with a time constant of 50 to 200 ms. Obviously, this method cannot be employed initially and so pre-set average values are used as initial starting conditions. With an average value determined, upper and lower thresholds may be used to test any variation in the ion beam current. The thresholds are measured relative to the average ion beam current and may be offset from that average by differing amounts. The offset may, for example, correspond to a drop of 50%. The thresholds are often specific to a particular implantation recipe. Either every single ion beam current measurement can be compared against the thresholds or a small number of consecutive measurements can themselves be averaged before comparison to the thresholds (e.g. measure I_{TOTAL} with a short time constant of 1 ms). A further condition may be imposed that consecutive readings (e.g. ten) should exceed the thresholds before the ion beam is switched off.

As described previously, detection of an ion beam glitch leads to the ion beam 23 being switched off. This may be achieved in any number of ways, although it is clearly advantageous to achieve a rapid extinction of the ion beam 23. To date, an ion beam 23 has been extinguished by interrupting the power input to the arc power supply unit 62. However, it is relatively slow, taking in excess of 20 ms. An alternative method of extinguishing the ion beam 23 that is far quicker is now described.

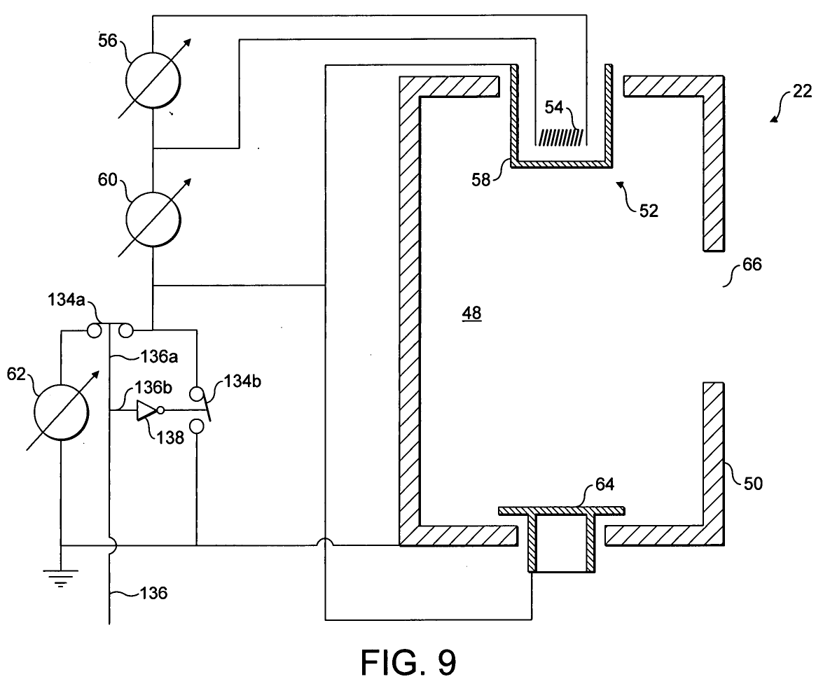

FIG. 9 shows an ion source 22 akin to that shown in FIG. 2 and therefore like reference numerals will be used for like parts. In addition, repetitive description will be avoided. Inspection of FIG. 9 compared to FIG. 2 shows that the circuit around the arc power supply unit 62 has been modified to include a pair of power semiconductor switches 134a,b. The power semiconductor switches 134a,b allow rapid switching, typically less than 20 ms.

The power semiconductor switches 134a,b are supplied with command signals derived from a common line indicated at 136 in FIG. 9. It will be seen that this line 136 bifurcates with one portion 136a being supplied to a first switch 134a and the other portion 136b of the signal being supplied to the second switch 134b via a NOT gate 138. This ensures that the pair of switches 134a,b are operated mutually exclusively, i.e. the first switch 134a is open when the second switch 134b is closed and vice versa. In the configuration shown in FIG. 9, the first switch 134a is closed and the second switch 134b is open such that the ion source 22 is biased by the arc supply 62 to ensure a potential difference between anode 50 and cathode 52. This ensures ion creation and hence provides an ion beam 23 for implanting the wafer 36.

Reversing the signal on line 136 inverts the two switches 134a,b so that the first switch 134a is open and the second switch 134b is closed. This isolates the arc supply 62 to connect directly the chamber walls 50 to the tube 58 of the indirectly heated cathode 52. The resulting zero potential difference between anode 50 and cathode 52 causes immediate collapse of the plasma and immediate extinction of the ion beam 23.

The collapse of the plasma in this way will cause the ion source chamber 38 to cool down. Restarting the ion source 22 from cold will prolong the time for the ion beam 23 to settle to the previous steady flux value. This can be avoided by increasing the power delivered to the filament 54 or across the filament 54 and tube 58 using the bias power supply 60.

Reversing the signal on line 136 once more leads to rapid creation of an ion beam 23 because the two switches 134a,b are inverted such that the anode 50 is biased relative to the cathode 52 and ions are created by the ion source 22. This is helped by keeping the chamber 48 hot, as described above.

As will be appreciated by the skilled person, variations may be made to the embodiments described above without departing from the scope of the amended claims.

Examples of scanning schemes are presented in FIGS. 4 to 6, but these are merely examples and the present invention may be employed with other schemes. It will be readily apparent that the present invention may be adapted to any scheme where an ion beam 23 is scanned relative to a substrate along one or more pre-defined paths. The paths may be linear, arcuate or may follow any other shape. For example, a spiral scan may be used where the ion beam follows a spiral path around the wafer. If raster scans are used, the scan lines need not be parallel, for example the ion beam may follow a zig-zag pattern. Where movement along the path may be reciprocated, the method illustrated in FIGS. 4 and 5 may be used. Where movement may not be reciprocated, the method illustrated in FIG. 5 may be used.

The present invention may also be used with different overall scanning schemes. For example, the present invention may be used with an interlaced series of raster scans 68, i.e. where only certain scan lines 70 are allowed on one pass, other missed scan lines 70 being implanted on the next pass. For example, the first pass may implant the first, fifth, ninth, . . . scan lines 70 of FIG. 4a, the second pass may implant the second, sixth, tenth, . . . scan lines 70, the third pass may implant the third, seventh, eleventh, . . . scan lines 70 and the fourth, eighth, twelfth, . . . scan lines 70. The wafer 36 may be rotated through 180° between passes. Alternatively a series of raster scans 68 may be performed following the same pattern: the wafer 36 may be rotated (say by 90°, or any other angle) between passes so that each raster pattern 68 is at an angle to the other patterns 68.

The above embodiments of the present invention are all used in the context of serial processing of wafers 36 using raster scans 68. As mentioned previously, scanning may be achieved by (a) translating the wafer 36 relative to a fixed ion beam 23, (b) deflecting an ion beam 23 across a fixed wafer 36 or (c) using a hybrid method of translating the wafer 36 and deflecting the ion beam 23. In addition, the present invention may be used with batch processing of wafers 36 where an ion beam 23 scans over each wafer along a plurality of scan lines 70. For example, the invention may be used with a batch implanter comprising a spoked-wheel wafer holder (i.e. a plurality of wafers are held at the ends of a number of spokes extending from a central hub).

The method given above for determining the ion beam 23 current is merely one example of doing so. The ion beam 23 current may also be determined by monitoring the beam line power supplies (e.g. the pre-acceleration power supply, the lens voltage power supply, the deceleration power supply), monitoring the current flowing from the chuck to ground or by using a current clamp method. The current clamp method comprises placing a solenoid around a part of the ion beam path 23. Any change in ion beam current will cause a change in the current flowing through the solenoid. Thus, ion beam glitches can be detected by measuring the current flowing through the solenoid.

The arrangement shown in FIG. 9 is particularly well suited to extinguishing and starting the ion beam 23 due to its rapid switching speed. However, it is but one method of turning the ion beam 23 on and off. Other possibilities include changing the pre-acceleration voltage, changing the extraction voltage, changing the magnetic field in the mass-analysing arrangement or closing the mass-resolving slit.

FIG. 9 shows an ion source 22 having an indirectly heated cathode 52. The ion source 22 need not use an indirectly heated cathode 52 and could instead be of a single filament 54 design. In this design, a filament 54 is used as the cathode 52 to emit electrons directly into the ion source chamber 48 and is often located directly in front of an electron reflector biased to ensure electrons are accelerated away from filament 54. In this arrangement, only one power supply unit is needed to supply current to the filament 54, i.e. the filament supply 56 and bias supply 60 of FIG. 9 are replaced by a single supply 62 that provides current to the filament 54. An arc power supply unit is again used to create a potential difference between anode 50 and cathode 52. Alternatively, a Freeman-type cathode may be used.

1. A method of implanting ions in a substrate using an ion beam having cross-sectional dimensions smaller that the substrate comprising the steps of:
(a) establishing a stable ion beam with the substrate clear of the ion beam;
(b) implanting the substrate by causing relative motion between the ion beam and the substrate such that the ion beam traverses the substrate along at least one path;
(c) monitoring the ion beam for instabilities during step (b);
(d) upon detecting an ion beam instability, switching off the ion beam as the relative motion continues to leave an unimplanted portion of the path;
(e) recording an off position corresponding to the ion beam's position relative to the substrate when the ion beam is switched off in step (d);
(f) establishing a stable ion beam once more; and
(g) continuing to implant the substrate by causing relative motion between the ion beam and the substrate along the unimplanted portion of the path.

2. A method according to claim 1, wherein step (f) comprises establishing a stable ion beam with the substrate clear of the ion beam prior to step (g); step (g) comprises causing relative motion between the ion beam and the substrate such that the ion beam travels along said path in a reverse direction, that is in an opposite direction as for step (b), and switching off the ion beam when the ion beam crosses the off position.

3. A method according to claim 1, wherein step (g) comprises switching the ion beam on at the off position prior to the ion beam traversing the unimplanted portion of said path in the forward direction, that is the same direction as for step (b).

4. A method according to claim 3, wherein step (g) comprises causing relative motion between the ion beam and substrate in the forward direction from a point along said path such that the ion beam is switched on during the relative motion upon crossing the off position.

5. A method according to claim 2, further comprising: repeating steps (c), (d) and (e) during step (g) such that, if a second beam instability is detected, a central portion of said path is not implanted; and continuing to implant the substrate once more by causing relative motion between the ion beam and the substrate such that the ion beam travels across the substrate along the central portion of said path.

6. A method according to claim 5, comprising the steps of: commencing the relative motion along said path outside of the central portion; switching the beam on when first crossing an off position; and switching the beam off when crossing the other off position.

7. A method according to claim 1, wherein step (c) comprises monitoring a return current.

8. A method of implanting ions in a substrate held in a substrate holder moveable bidirectionally along a first axis of translation, the method comprising the steps of:
(a) establishing a stable ion beam having cross-sectional dimensions smaller than the substrate with the ion beam clear of the substrate in a start position adjacent the substrate along the first axis;
(b) implanting the substrate by moving the substrate holder along the first axis such that the ion beam transverses the substrate along a first scan line and continues until clear of the substrate;
(c) causing relative motion between the ion beam and the substrate holder along a second axis;
(d) repeating steps (b) and (c) to implant a series of scan lines across the substrate;
(e) monitoring the ion beam during implantation in step (b) and as repeated according to step (d);
(f) upon detecting an ion beam instability, switching off the ion beam as the relative motion continues to leave an unimplanted portion of the scan line;
(g) recording an off position corresponding to the position of the substrate holder when the ion beam is switched off in step (f);
(h) establishing a stable ion beam once more;
(i) completing implantation of the scan line by moving the substrate holder along the first axis so that the ion beam scans over the unimplanted portion of the scan line; and
(j) completing implantation of the substrate by repeating steps (b) and (c) to complete the series of scan lines across the substrate.

9. A method according to claim 8, wherein step (c) comprises translating the substrate holder along a second axis of translation relative to a fixed ion beam, the first and second axes being perpendicular.

10. A method according to claim 8, wherein step (f) comprises continuing to move the substrate holder along the first axis after the ion beam is switched off such that, if the ion beam were still switched on, the ion beam completes the scan line and stops at a stop position.

11. A method according to claim 10, wherein step (h) comprises establishing a stable ion beam with the ion beam clear of the substrate at the stop position; step (i) comprises moving the substrate holder along the first axis to follow the scan line in the reverse direction and switching off the ion beam during the movement of step (i) when the substrate holder passes through the off position.

12. A method according to claim 9, wherein step (h) comprises establishing a stable ion beam with the ion beam clear of the substrate at the stop position; step (i) comprises moving the substrate holder along the first axis to follow the scan line in the reverse direction and switching off the ion beam during the movement of step (i) when the substrate holder passes through the off position and further comprising the step of determining whether the ion beam will strike the substrate holder upon restarting the ion beam in step (h) and, if yes, causing an effective relative motion between the ion beam and substrate holder along the second axis to a position where the ion beam can be established without striking the substrate or substrate holder before reciprocating the relative motion back to the stop position to allow step (i) to be performed.

13. A method according to claim 8, further comprising the steps of: moving the substrate holder along the scan line in the reverse direction with the ion beam still switched off such that, if the ion beam were switched on, the ion beam returns to the start position; moving the substrate holder back along the scan line in the forwards direction to complete the scan line with the ion beam initially switched off; and restarting the ion beam during the movement back along the scan line in the forwards direction when the substrate holder passes through the off position.

14. A method according to claim 11, further comprising:
repeating steps (e), (f) and (g) during step (i) such that, if a second beam instability is detected whilst scanning in the reverse direction, a central portion of the scan line is not implanted;
stopping movement of the substrate holder after the ion beam has been switched off for the second time at a second off position; and
moving the substrate holder back along the scan line in the forward direction and, during this movement, turning the ion beam on when the substrate holder passes through the second off position and turning the ion beam off when the substrate holder passes through the first off position.

15. A method according to claim 8, wherein step (e) comprises monitoring a return current.

16. An ion implanter controller for an ion implanter operable to generate an ion beam for implanting into a substrate wherein the ion beam has cross-sectional dimensions smaller than the substrate, the controller comprising:
ion beam switching means operable to cause the ion beam to switch on and off;
scanning means operable to cause relative motion between the ion beam and the substrate such that the ion beam traverses the substrate along at least one path;
ion beam monitoring means operable to receive a signal indicative of the ion beam flux and to detect instabilities in the ion beam therefrom during said relative motion; and
indexing means operable to determine the position of the ion beam relative to the substrate during said relative motion;
wherein the controller is arranged such that:
the ion beam switching means is operable to cause the ion beam to switch off during the relative motion when the ion beam monitoring means detects an instability in the ion beam to leave an unimplanted portion of the path;
the indexing means records an off position of the ion beam relative to the substrate when the ion beam is switched off;
the ion beam switching means is operable to cause the ion beam to switch on once more; and
the scanning means is operable to cause relative motion between the ion beam and the substrate such that the ion beam traverses the substrate along the unimplanted part of the path.

17. A controller according to claim 16, wherein the controller is arranged such that:
the scanning means is operable to ensure the substrate is not in the way of the ion beam when the ion beam switching means cause the ion beam to switch on once more;
the ion beam monitoring means is operable to determine whether or not the ion beam is stable;
once the ion beam monitoring means indicates the ion beam to be stable, the scanning means is operable to cause relative motion between the substrate and ion beam such that the ion beam travels along said path in a reverse direction; and
the ion beam switching means is operable to cause the ion beam to switch off when the ion beam passes through the off position.

18. A controller according to claim 16, wherein the controller is arranged such that:
the scanning means is operable to cause effective relative motion between the ion beam and the substrate with the ion beam initially switched off such that, if the ion beam were switched on, the ion beam traverses at least a portion of the path in the same forwards direction, the portion including the unimplanted part of the path; and
the ion beam switching means is operable to cause the ion beam to switch on when the ion beam passes through the off position.

19. An ion implanter for implanting a substrate using an ion beam, comprising:
an ion source operable to generate the ion beam;
an ion beam monitor operable to detect instabilities in the ion beam;
a substrate holder moveable bidirectionally along a first axis of translation and operable to hold the substrate to be implanted; and
the controller of claim 16;
wherein:
the ion beam switching means is operable to cause the ion source to switch on or off thereby causing the ion beam to switch on and off;
the scanning means is operable to cause the substrate holder to move along the first axis thereby causing the ion beam to traverse the substrate along at least one path; and
the ion beam monitor is operable to supply the signal to the ion beam monitoring means upon detecting an instability.

20. An ion implanter according to claim 19, wherein the ion beam monitor is a return current detector.

21. An ion source for an ion implanter comprising: a cathode, an anode, biasing means for biasing the anode relative to the cathode, a first switch, and a first electrical path connecting anode to cathode via the biasing means and the first switch arranged in series, wherein the first switch is operable to make or break the first electrical path.

22. An ion source according to claim 21, further comprising a second conductor path connecting anode to cathode with at least a portion that extends in parallel across the biasing means, the portion comprising a second switch operable to make or break the second electrical path.

23. An ion source according to claim 22, wherein the first switch is operable in response to a first binary switching signal and the second switch is operable in response to a second binary switching signal that is the complement of the first switching signal.

24. An ion source according to claim 23, further comprising a not gate operable to generate the complementary second switching signal from a portion of the first switching signal.

25. An ion source according to claim 21, wherein the first switch is a power semiconductor switch.

26. An ion source according to claim 22, wherein the second switch is a power semiconductor switch.

27. An ion implanter including the ion source of claim 21.

28. A method of switching off the ion source of claim 21, comprising the step of operating the first switch to break the first electrical path in response to detection of an instability in the ion beam generated by the ion source.

29. A method according to claim 28, further comprising increasing the power supplied to the cathode.

30. A method according to any of claim 1, wherein the step of switching off the ion beam comprises switching off an ion source in accordance with claim 29.
